(19) United States
(12) Patent Application Publication
(10) Pub. No.: US 2008/0186765 A1
(43) Pub. Date: Aug. 7, 2008

(54) SEMICONDUCTOR MEMORY DEVICE

(76) Inventor: Takeshi KAMIGAICHI, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/020,628

(22) Filed: Jan. 28, 2008

(30) Foreign Application Priority Data
Jan. 30, 2007 (JP) 2007-020014

(51) Int. Cl. G11C 16/04

(52) U.S. Cl. 365/185.05; 365/185.17

(57) ABSTRACT

A semiconductor memory device according to one example includes a first cell transistor series including memory cell transistor connected in series, a first selecting transistor whose one terminal is connected to one terminal of the first cell transistor series, a second selecting transistor connected between the other terminal of the first selecting transistor and a bit line, and a third selecting transistor connected between the other terminal of the first cell transistor series and a source line. The first and second selecting transistors have a first conductive film, an inter-electrode insulating film and a second conductive film which are stacked on a semiconductor substrate. In one of the first and second selecting transistors, the first and second conductive films are connected to each other, and in the other transistor, the first and second conductive films are separated from each other.

### CROSS-REFERENCE TO RELATED APPLICATIONS

This application is based upon and claims the benefit of priority from prior Japanese Patent Application No. 2007-020014, filed Jan. 30, 2007, the entire contents of which are incorporated herein by reference.

### BACKGROUND OF THE INVENTION

1. Field of the Invention

The present invention relates to a semiconductor memory device, for example, a stacked-gate transistor which has a floating gate electrode and a control gate electrode stacked via an inter-electrode insulating film.

2. Description of the Related Art

As nonvolatile semiconductor memory devices which feature electrical rewriting and high integration, NAND flash electrically erasable programmable read-only memories (EEPROMs) are known. A memory cell transistor of a NAND flash EEPROM has a stacked-gate structure. The stacked-gate structure has a tunnel insulating film, a floating gate electrode for accumulating electric charges, an inter-electrode insulating film and a control gate electrode which are stacked on a substrate.

A structure wherein a plurality of memory cell transistors are connected in series and two select gate transistors which are connected to both terminals of the structure constitute a NAND string. A plurality of NAND strings are arranged sequentially in a row direction so as to constitute a memory cell array. Gate electrodes of the plurality of gate transistors belonging to the same row are connected to each other, and the control gate electrodes of the memory cell transistors belonging to the same row are connected to each other.

The select gate transistor at one terminal in the NAND string is connected to a source line via a source line contact plug, and the select gate transistor at the other terminal is connected to a bit line via a bit line contact plug.

Potentials to be applied from the source line to the respective NAND strings are equal to one another. For this reason, the contact plug (source line contact plug) which connects the source line and the select gate transistor (source line side select gate transistor) may be over active regions of the plurality of source line side select gate transistors. Therefore, even when miniaturization is improved in the formation of the source line contact plug, few restrictions are imposed.

On the other hand, since the bit line is provided individually for each NAND string, the respective bit lines should be insulated from each other. For this reason, the contact plug (bit line contact) which connects the bit line and the select gate transistor must not arrive at active regions other than the active region to which the contact plug should be connected. For this reason, as the miniaturization is improved, the formation of a bit line contact becomes more difficult.

In order to solve this problem, there has been proposed a structure wherein two bit line side select gate transistors which have different thresholds and are connected in series are provided to each NAND string. When the two bit line side select gate transistors are suitably turned on/off, only one of the two NAND strings adjacent in the row direction can be electrically connected to the bit line. With this technique, the adjacent two NAND strings can commonly use one bit line. Therefore, one contact plug can be used commonly by the two NAND strings, and the restriction to the formation of the bit line contact plug is alleviated. Therefore, the miniaturization of the semiconductor memory devices can be further improved.

The two bit line side select gate transistors having different thresholds are realized by injecting different impurities into channel regions of the two gate transistors. However, an area of the channel region of the select gate transistor becomes very smaller as the miniaturization is improved. In order to inject two kinds of impurities into the fine regions, a processing device which requires a precision process is necessary, thereby increasing a manufacturing cost of the semiconductor memory devices.

A prior art document relating to the invention of this application is Jpn. Pat. Appln. KOKAI Publication No. 06-275800.

### BRIEF SUMMARY OF THE INVENTION

A semiconductor memory device according to one aspect of the present invention comprises a first cell transistor series including memory cell transistor connected in series, a first selecting transistor whose one terminal is connected to one terminal of the first cell transistor series, a second selecting transistor connected between the other terminal of the first selecting transistor and a bit line, and a third selecting transistor connected between the other terminal of the first cell transistor series and a source line. The first and second selecting transistors have a first conductive film, an inter-electrode insulating film and a second conductive film which are stacked on a semiconductor substrate. In one of the first and second selecting transistors, the first and second conductive films are connected to each other, and in the other transistor, the first and second conductive films are separated from each other.

A semiconductor memory device according to one example of the present invention comprises a first cell transistor series and a second cell transistor series arranged adjacently in a row direction, each having memory cell transistors connected in series, a first selecting transistor whose one terminal is connected to one terminal of the first cell transistor series, a second selecting transistor connected between the other terminal of the first selecting transistor and a first bit line, a third selecting transistor connected between the other terminal of the first cell transistor series and a source line, a fourth selecting transistor whose one terminal is connected to one terminal of the second cell transistor series, a fifth selecting transistor connected between the other terminal of the fourth selecting transistor and a second bit line, and a sixth selecting transistor connected between the other terminal of the second cell transistor series and the source line. The first, second, fourth and fifth selecting transistors have a first conductive film, an inter-electrode insulating film and a second conductive film which are stacked on a semiconductor substrate. In the first and fifth selecting transistors, the first and second conductive films are connected to each other, and in the second and fourth selecting transistors, the first and second conductive films are separated from each other.

### BRIEF DESCRIPTION OF THE SEVERAL VIEWS OF THE DRAWING

FIG. 1 is a functional block diagram illustrating a semiconductor memory device according to one embodiment of the present invention;

FIG. 2 is a top view illustrating the semiconductor memory device according to one embodiment of the present invention;

FIG. 3 is a cross-sectional view illustrating one part of FIG. 2;

FIG. 4 is a cross-sectional view illustrating one state of manufacturing steps for the semiconductor memory device in FIG. 3;

FIG. 5 is a cross-sectional view at steps continuous from FIG. 4;

FIG. 6 is a cross-sectional view at steps continuous from FIG. 5;

FIG. 7 is a cross sectional view at steps continuous from FIG. 6;

FIG. 8 is a cross-sectional view at steps continuous from FIG. 7;

FIG. 9 is a cross sectional view at steps continuous from FIG. 8;

FIG. 10 is a cross-sectional view continuous from FIG. 9;

FIG. 11 is a cross-sectional view at steps continuous from FIG. 10;

FIG. 12 is a plan view illustrating one state at the time of operating the semiconductor memory device according to one embodiment of the present invention;

FIG. 13 is a cross-sectional view illustrating one part of FIG. 12;

FIG. 14 is a cross-sectional view illustrating one part of FIG. 12;

FIG. 15 is a plan view illustrating one state at the time of operating the semiconductor memory device according to one embodiment of the present invention;

FIG. 16 is a cross-sectional view illustrating one part of FIG. 15; and

FIG. 17 is a cross-sectional view illustrating one part of FIG. 15.

### DETAILED DESCRIPTION OF THE INVENTION

A semiconductor memory device of an aspect of the present invention will be described below in detail with reference to the accompanying drawings.

Embodiments of the present invention will be described below with reference to the drawings. In the following description, components having approximately the same functions and constitutions are denoted by the same reference numerals, and overlapped description is given only if necessary. The drawings are pattern diagrams, and thus it should be noted that a relationship between a thickness and a plane dimension and ratios of respective layer thicknesses are different from actual ones. Therefore, concrete thicknesses and dimensions should be determined after the following description is taken into consideration. Needless to say, in the respective drawings, some dimensional relationships and ratios vary.

The following embodiments illustrate a device and a method for embodying a technical idea of the present invention, and as to the technical idea of the present invention, a material, a shape, a constitution and an arrangement of the components are not limited to the followings. The technical idea of the present invention can be variously modified within a scope of claims.

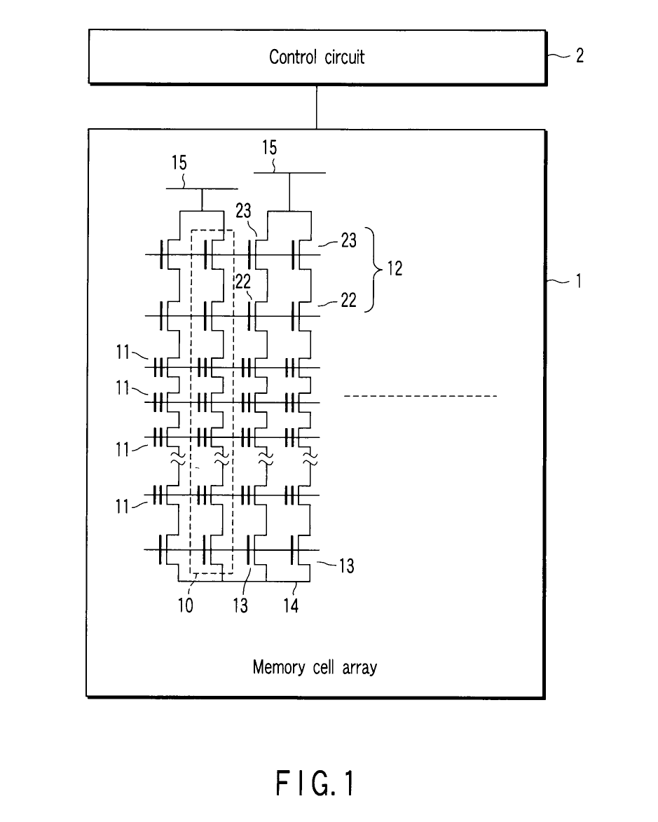

FIG. 1 is a functional block diagram illustrating a constitution of a main section of the semiconductor memory device according to one embodiment of the present invention. As shown in FIG. 1, the semiconductor memory device includes a memory cell array 1 and a control circuit 2.

The memory cell array 1 includes a plurality of NAND strings 10. The NAND string is comprised of a plurality of memory cell transistors 11 which are connected in series, a select gate 12, and a select gate transistor 13. The plurality of NAND strings 10 are provided in a direction (the right-to-left [row] direction in the drawing) crossing a direction in which the NAND strings extend.

Each memory cell transistor 11 is comprised of a so-called stacked-gate-structure metal oxide semiconductor field-effect transistor (MOSFET). The stacked-gate-structure MOS transistor includes a tunnel insulating film, a floating gate electrode, an inter-electrode insulating film, a control gate electrode and a source/drain diffusion layer as detailed later. Each of the memory cell transistors 11 stores information according to electrons accumulated on the floating gate electrode. The plurality of memory cell transistors 11 are connected in series so as to constitute a memory cell column.

One terminal of each memory cell column is connected to one terminal of the select gate transistor 13. The select gate transistor 13 is comprised of a normal MOSFET, and may be realized by, for example, connecting the control gate electrode and the floating gate control of the stacked-gate-structure MOSFET. The other terminal of the select gate transistor 13 is connected to a source line 14 via a source line contact plug.

The other terminal of each memory cell column is connected to the select gate 12. The select gate 12 controls electrical connection and non-connection between the other terminal of the memory cell column and a bit line 15.

The select gate 12 is comprised of at least two stacked-gate-structure select gate MOSFETs (hereinafter, a MOSFET is referred to as a transistor) 22 and 23 which are connected in series. The select gate transistors 22 and 23 also include a tunnel insulating film, a floating gate electrode, an inter-electrode insulating film, a control gate electrode and a source/drain diffusion layer.

As detailed later, one control gate electrode is connected to the floating gate electrode in the select gate transistors 22 and 23 in one NAND string. One terminal of the select gate transistor 22 is connected to the other terminal of the memory cell column, and the other terminal is connected to one terminal of the select gate transistor 23. The adjacent two NAND strings constitute one set in the row direction, and the other terminals of the two select gate transistors 23 in the NAND strings composing the set are connected to one bit line 15 via the bit line contact plug.

The control gate electrodes of the adjacent memory cell transistors 11 (belonging to the same row) in the row direction are connected to each other. The gate electrodes of the adjacent select gate transistors 13 (belonging to the same row) in the row direction are connected to each other. The control gate electrodes of the adjacent select gate transistors 22 (belonging to the same row) in the row direction are connected to each other, and the control gate electrodes of the adjacent select gate transistors 23 (belonging to the same row) in the row direction are connected to each other.

The control circuit 2 has a plurality of circuit elements such as decoders, sense amplifiers and potential generating circuits which are necessary for writing or reading predetermined data to/from a memory cell according to an external signal.

The gate electrode of the select gate transistor 13, the control gate electrodes of the select gate transistors 22 and 23, and the control gate electrode of the memory cell 11 are connected to the control circuit 2. The control circuit 2 (the potential generating circuit in the control circuit 2) can apply one or two or more kinds of potentials to the gate electrode of the select gate transistor 13, the control gate electrode of the select gate transistor 22, the control gate electrode of the select gate transistor 23, and the control gate electrode of the memory cell 11 independently in each row.

The bit line contact plug and the source line contact plug are commonly used by the adjacent two NAND strings in a column direction (direction in which the NAND string extends). Therefore, the NAND string has a constitution symmetrical with respect to the bit line contact plug and the source line contact plug.

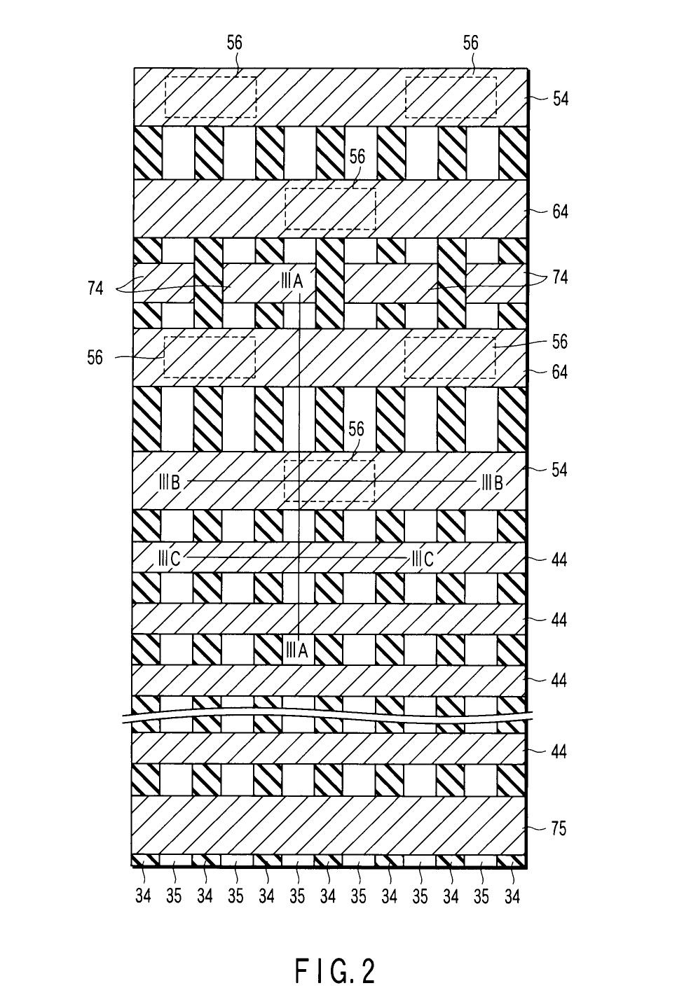

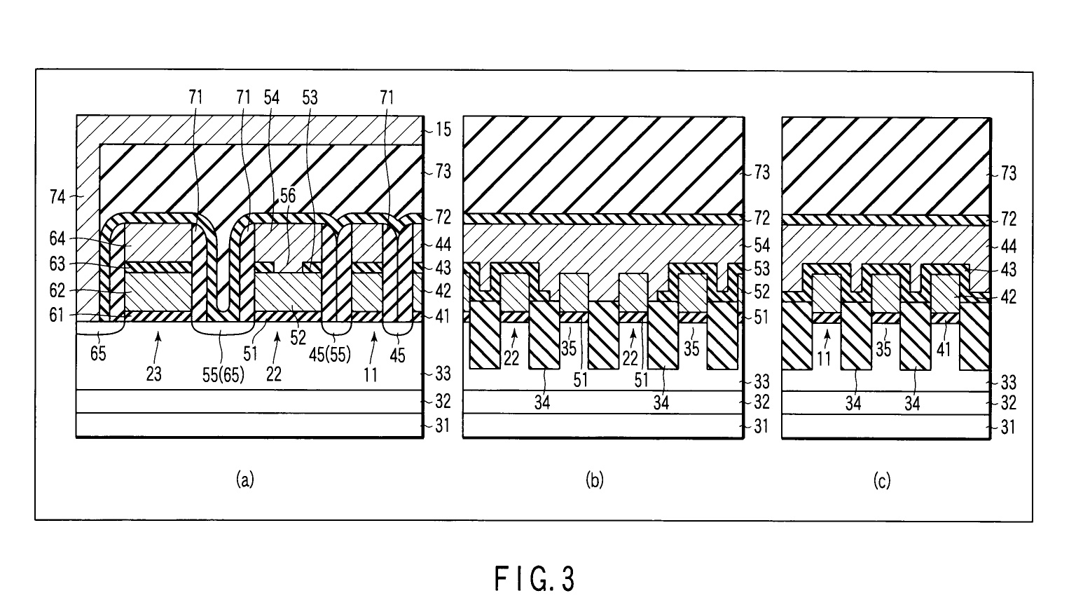

The structure of the semiconductor memory device according to one embodiment of the present invention will be described below with reference to FIGS. 2 and 3. FIG. 2 is a schematic top view illustrating a main section of the semiconductor memory device according to one embodiment of the present invention. FIG. 3(a) is a cross-sectional view schematically illustrating the main section taken along line IIIA-IIIA of FIG. 2. FIG. 3(b) is a cross-sectional view schematically illustrating the main section taken along line IIIB-IIIB of FIG. 2. FIG. 3(c) is a cross-sectional view schematically illustrating the main section taken along line IIIC-IIIC of FIG. 2.

As shown in FIGS. 2 and 3, an n-type well 32 is formed on a surface of a silicon substrate 31. A p-type well 33 is formed in the well 32. An element separation insulating film 34 is formed on the surface of the substrate 31. The separation insulating film 34 has, for example, a shallow trench isolation (STI) structure, and divides an element region 35, and protrudes from the surface of the substrate 31 to extend to a top-to-bottom direction in FIG. 2.

The memory cell transistor 11, the select gate transistors 22 and 23 are formed on the substrate 31 in the element region 35.

The memory cell transistor 11 has at least a tunnel insulating film 41, a floating gate electrode 42, an inter-electrode insulating film 43 and a control gate electrode 44.

The select gate transistor 22 has at least a tunnel insulating film 51, a floating gate electrode 52, an inter-electrode insulating film 53 and a control gate electrode 54.

The select gate transistor 23 has at least a tunnel insulating film 61, a floating gate electrode 62, an inter-electrode insulating film 63 and a control gate electrode 64.

The tunnel insulating films 41, 51 and 61 are provided onto the substrate 31 in the element region 35, and are practically comprised of a silicon oxide film, for example. The floating gate electrodes 42, 52 and 62 are provided on the tunnel insulating films 41, 51 and 61, respectively. Their lower portions are formed so as to be self-aligned with respect to the separation insulating film 34, and their upper portions protrude from the element separation insulating film 34. The floating gate electrodes 42, 52 and 62 are practically comprised of a conductive polysilicon film, for example. All the floating gate electrodes 42, 52 and 62 are electrically independent of each other.

The control gate electrode 44 is formed on the inter-electrode insulating film 43, and is practically comprised of conductive polysilicon, for example.

The control gate electrodes 54 and 64 are formed on the inter-electrode insulating films 53 and 54, respectively, and are practically comprised of conductive polysilicon, for example. The control gate electrodes 54 and 64 are formed on the floating gate electrodes 52 and 62 in a removal portion 56 of the inter-electrode insulating films 53 and 63, mentioned later, respectively.

The control gate electrodes 44, 54 and 64 may have a stacked structure.

The control gate electrodes 44 of the adjacent cell transistors 11 in the row direction are connected to each other, and extend to the row direction (the right-to-left direction in FIG. 2). Similarly, the control gate electrodes 54 of the adjacent select gate transistors 22 in the row direction are connected to each other, and extend to the row direction. The control gate electrodes 64 of the adjacent select gate transistors 23 in the row direction are connected to each other, and extend to the row direction.

The inter-electrode insulating films 43, 53 and 63 cover the surfaces of the floating gate electrodes 42, 52 and 62, respectively, and are formed on the separation insulating film 34. The inter-electrode insulating films 43, 53 and 63 are comprised of, for example, stacked silicon oxide film, silicon nitride film and silicon oxide film.

The inter-electrode insulating films 53 and 63 partially have a removal portion 56 according to the following rule. In the removal portion 56, the inter-electrode insulating films 53 and 63 are removed, and the floating gate electrodes 52 and 62 are partially exposed, so that the control gate electrodes 56 and 64 contact with the exposed portions, respectively. The removal portion 56 connects the floating gate electrode 56 to the control gate electrode 54 in a certain select gate transistor 22, and connects the floating gate electrode 62 to the control gate electrode 64 in a certain select gate transistor 23.

As described with reference to FIG. 1, in one of the select gate transistors 22 and 23 in one NAND string 10, the floating gate electrodes 52 and 62 are connected to the control gate electrodes 54 and 64, respectively. In addition, in only one of the two select gate transistors 22 and only one of the two select gate transistors 23 in the two NAND strings 10 commonly using the bit line 15, the floating gate electrodes 52 and 62 are connected to the control gate electrodes 54 and 64, respectively. In order to realize the connections according to the above rule, the removal portion 56 is formed on only one of the select gate transistors 22 and 23 in a certain NAND string 10, only one of the two select gate transistors 22 in the two NAND strings 10 commonly using the bit line 15, and only one of the two select gate transistors 23 in the two NAND strings 10.

When the floating gate electrodes 52 and 62 are connected to the control gate electrodes 54 and 64, respectively, on the removal portion 56, the concrete structure is not specifically restricted. For example, a length of the removal portion 56 in the column direction (top-to-bottom direction in FIG. 2) is smaller than a length of the floating gate electrodes 52 and 62 in the column direction. For this reason, as is clear from FIG. 3(a), the inter-electrode insulating films 53 and 63 can be allowed to remain on both terminals of the floating gate electrodes 52 and 62. However, the length of the removal portion 56 in the column direction may be the same as the length of the floating gate electrodes 52 and 62 in the column direction, namely, the inter-electrode insulating films 53 and 63 may be removed entirely along the target select gate transistors 22 and 23.

In the removal portion 56, the inter-electrode insulating films 53 and 63 on the side surfaces of the control gate electrodes 52 and 62 may be removed or may remain. The drawing illustrates a removed state.

The floating gate electrodes 52 and 62 are connected to the control gate electrodes 54 and 64, respectively in one of the select gate transistors 22 and 23 in one NAND string 10, and one of the two select gate transistors 22 and one of the two select gate transistors 23 in the two NAND strings 10 commonly using the bit line 15. When this rule is maintained, the two select gate transistors 22 and the two select gate transistors 23 in the two NAND strings 10 which do not commonly use the bit line 15 do not have to be governed by the rule. As shown in FIG. 2, the removal portion 56 may be formed so as to cover the two select gate transistors 22 or the two select gate transistors 23 in the two NAND strings 10 which do not commonly use the bit line 15. When this method is used, a length of the removal portion 56 in the row direction (right-to-left direction in FIG. 2) arrives at both terminals of the select gate transistors 22 (or 23) in the two NAND strings 10 which do not commonly use the bit line 15. According to this technique, in the case wherein the set which is comprised of the two select gate transistors 22 (or 23) adjacent along the row direction is one unit, the sets wherein the removal portion 56 is formed and the sets wherein the removal portion 56 is not formed are arranged alternately. This technique enables the removal portion 56 to be formed efficiently.

Source/drain regions 45, 55 and 65 are formed on the surface of the substrate 31 so as to sandwich the channel regions below the tunnel insulating films 41, 51 and 61, respectively, and consist of diffused impurity. The adjacent source-drain diffusion layers 45, 55 and 65 are commonly used by the adjacent memory cell transistor 11 and select gate transistors 22 and 23.

Side surfaces of the respective gate structures of the memory cell transistor 11 and the select gate transistors 22 and 23 (the tunnel insulating film, the floating gate electrode, the inter-electrode insulating film and the control gate electrode) in FIG. 3(a) are covered with an insulating film 71. The insulating film 71 is practically comprised of a silicon oxide film, for example.

The surface of the insulating film 71, the upper surfaces of the control gate electrodes 44, 54 and 64, and the surface of the substrate 31 of the memory cell transistors 11 and the select gate transistors 22 and 23 are covered with an insulating film 72. The insulating film 72 is practically comprised of a silicon nitride film, for example.

An inter-layer insulating film 73 is provided on an entire surface of the insulating film 72. The inter-layer insulating film 73 is practically comprised of a silicon oxide film such as boron phosphorous silicate glass (BPSG). The bit line 15 is provided on the surface of the inter-layer insulating film 73.

A contact plug 74 is provided on the source/drain diffusion layer 65 of the select gate transistor 23 opposite to the select gate transistor 22. The plug 74 is connected to a lower surface of the bit line 15. The plug 74 is provided along the active region 35 of the two NAND strings 10 commonly using the bit line 15.

Although not shown, the select gate transistor 13 to be connected to the source line 14 is also comprised of the stacked-gate-structure transistor similar to the cell transistor 11 and the select gate transistors 22 and 23. That is to say, the tunnel insulating film (gate insulating film), the floating gate electrode, the inter-electrode insulating film and the control gate electrode are sequentially stacked on the substrate 31. Source/drain regions are formed on the surface of the substrate 31 so as to sandwich the channel region below the tunnel insulating film. One of the source/drain regions is commonly used by the source/drain diffusion layer 45 of the cell transistor 11 at the end of the memory cell column, and the other is connected to the source line 14 via the contact plug.

The inter-electrode insulating films of all the select gate transistors 13 are partially removed similarly to the select gate transistor 22 in FIG. 3(a). The control gate electrode is connected to the floating gate electrode in the removed region. As a result, the select gate transistor 13 operates similarly to a normal MOS transistor. In FIG. 2, reference numeral 75 denotes a gate electrode of the select gate transistor 13, and it is commonly used by the select gate transistors 13 belonging to the same row.

As shown in FIG. 2, one NAND string 10, which is comprised of the memory cell transistor 11 and the select gate transistors 13, 22 and 23, is provided symmetrically with respect to the plug 74 and a plug for the source line 14 (not shown).

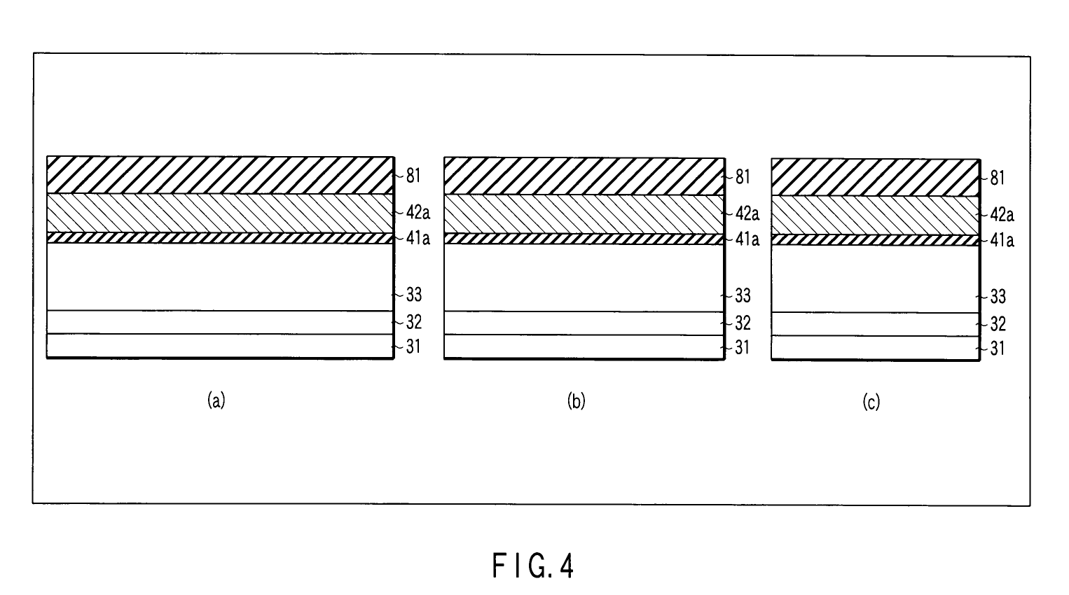

A method for manufacturing the semiconductor memory device in FIGS. 2 and 3 will be described below with reference to FIGS. 4 to 11. FIGS. 4(a), 5(a), 6(a), 7(a), 8(a), 9(a), 10(a) and 11(a) illustrate the structure of FIG. 3(a) in order of steps. FIGS. 4(b), 5(b), 6(b), 7(b), 8(b), 9(b), 10(b) and 11(b) illustrate the structure of FIG. 3(b) in order of steps. FIGS. 4(c), 5(c), 6(c), 7(c), 8(c), 9(c), 10(c) and 11(c) illustrate the structure of FIG. 3(c) in order of steps.

The structure of the select gate transistor 13 connected to the source line 13 is not shown, but is the same as those of the select gate transistors 22 and 23 except for the following portion. The difference is that although the inter-electrode insulating film 43 is removed or is not removed in the select gate transistors 22 and 23, an opening (removal portion) is formed on the inter-electrode insulating films of all the select gate transistors 13. Therefore, the description of the select gate transistor 13 is omitted. At the steps, however, the films which are used for forming the select gate transistors 22 and 23 are formed, removed, processed, and impurities are injected into the films also for the select gate transistor 13. As a result, the select gate transistor 13 is manufactured simultaneously with the select gate transistors 22 and 23.

As shown in FIG. 4, wells 32 and 33 are sequentially formed on the surface of the substrate 31 by ion injection. Impurities are injected into positions where channel regions are to be formed in order to control threshold voltages of the memory cell transistors 11, and the select gate transistors 22 and 23.

An insulating film 41a is formed on the entire surface of the substrate 31 by thermal oxidation, for example. The insulating film 41a becomes the tunnel insulating films 41, 51 and 61 by being patterned at later step. An electrically conductive film 42a is formed on the insulating film 41a by chemical vapor deposition (CVD) or ion injection, for example. The electrically conductive film 42a becomes the floating gates 42 and 52 by being patterned at later step. A mask material 81 consisting of a silicon nitride film, for example, is formed on the electrically conductive film 42a.

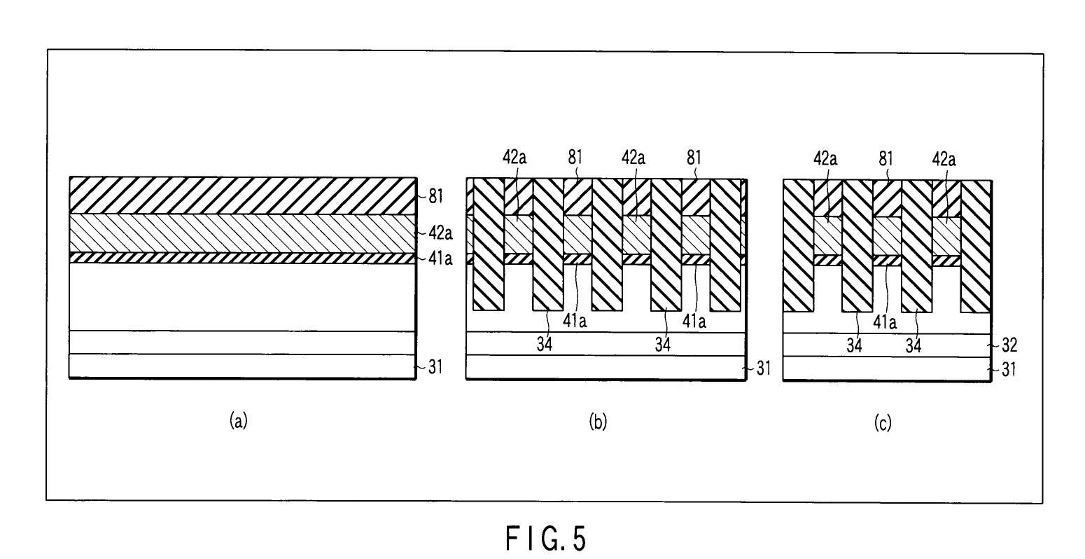

As shown in FIG. 5, an opening is formed on a region of the mask material 81 where the separation insulating film 34 is to be formed by a lithography step and anisotropic etching such as reactive ion etching (RIE). The mask material 81 is used as a mask, and a groove which pierces the electrically conductive film 42a and the insulating film 41a and reaches a part of the surface of the substrate 31 is formed by anisotropic etching such as RIE. An insulating film composing the separation insulating film 34 is embedded in the groove up to the same height as the mask material 81 by CVD or chemical mechanical polishing (CMP), for example.

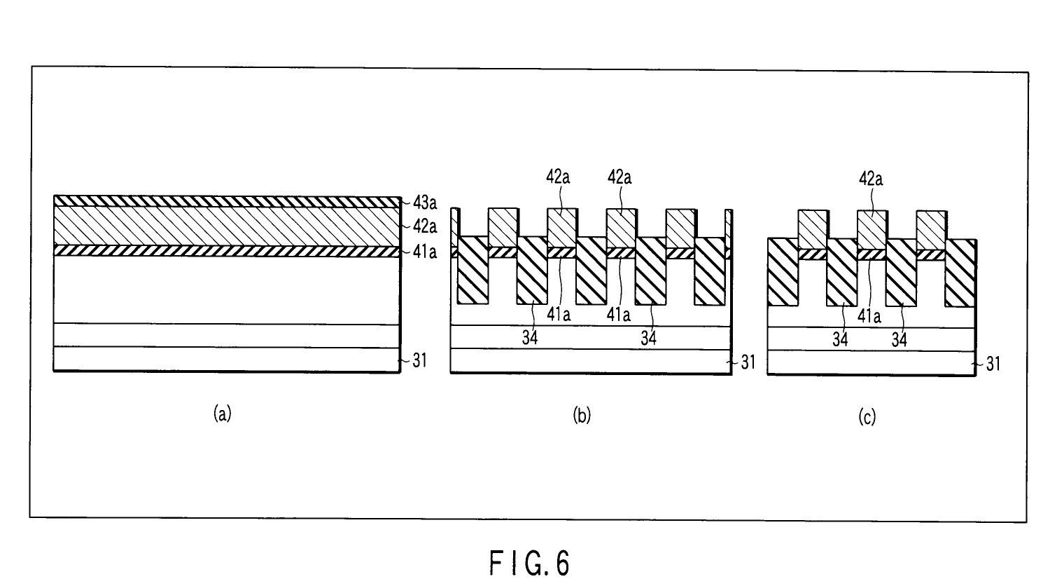

As shown in FIG. 6, the mask material 81 is removed. Then, the upper surface of the separation insulating film 34 is lowered to a position slightly higher than the insulating film 41a by etchback using RIE or the like.

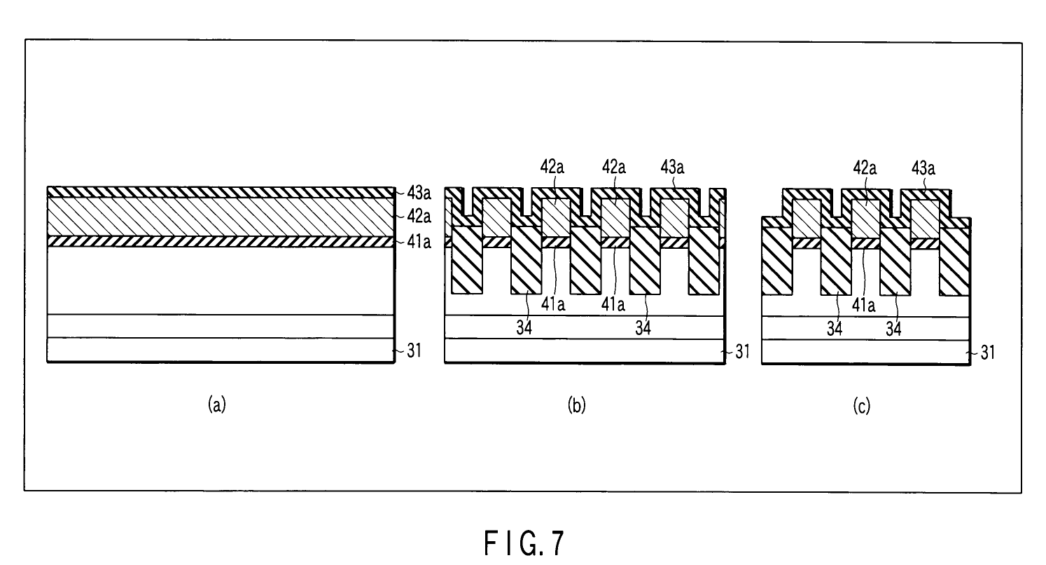

As shown in FIG. 7, an insulating film 43a is deposited on the entire surface of the structure obtained at these steps by CVD, for example. As a result, the insulating film 43a covers the upper surface of the separation insulating film 34 and the surface of the electrically conductive film 42a. The insulating film 43a is patterned at a later step, so as to become the inter-electrode insulating films 43, 53 and 63.

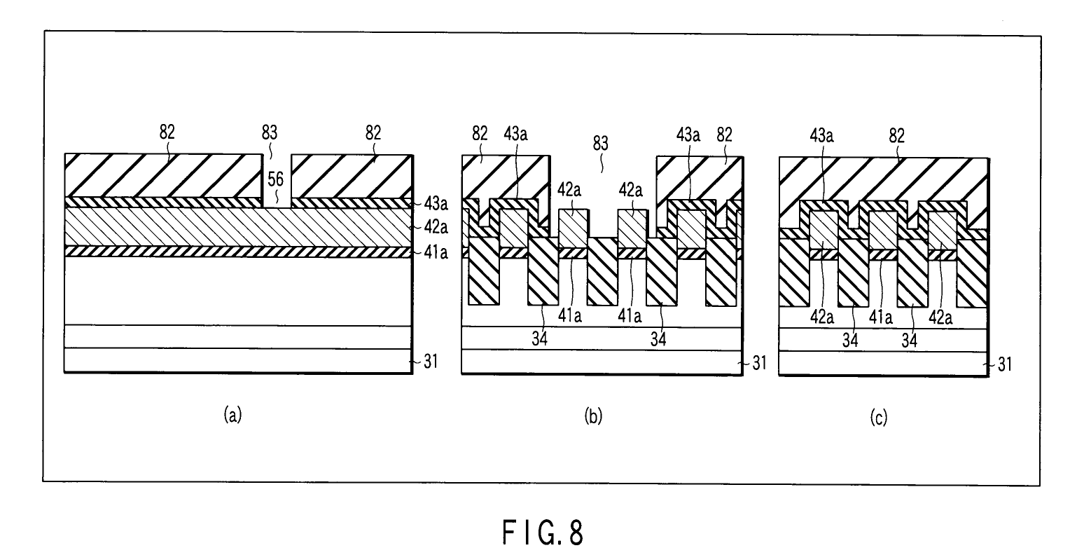

As shown in FIG. 8, a mask material 82 is formed on the entire surface of the insulating film 43a by CVD, for example. An opening 83 is formed on a region of the mask material 82 where the inter-electrode insulating films 53 and 63 are to be removed (region where the removal portion 56 is to be formed) by the lithography step, for example. The insulating film 43a is partially removed by the anisotropic etching such as RIE using the mask material 82 as a mask. As a result, the electrically conductive film 42a is exposed in the removal portion 56.

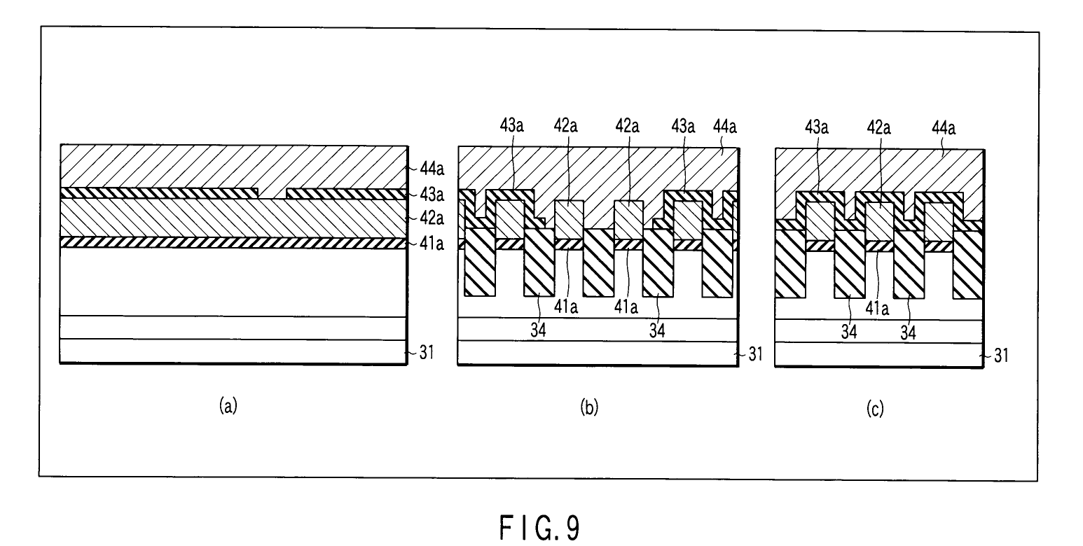

As shown in FIG. 9, the mask material 82 is removed. Then, an electrically conductive film 44a is formed on the entire surface of the structure obtained by the above steps by CVD, for example. The electrically conductive film 44a becomes the control gate electrodes 44, 54 and 64 by being patterned at a later step. At this step, the electrically conductive film 44a is formed on the surface of the insulating film 43a in the removal portion 56.

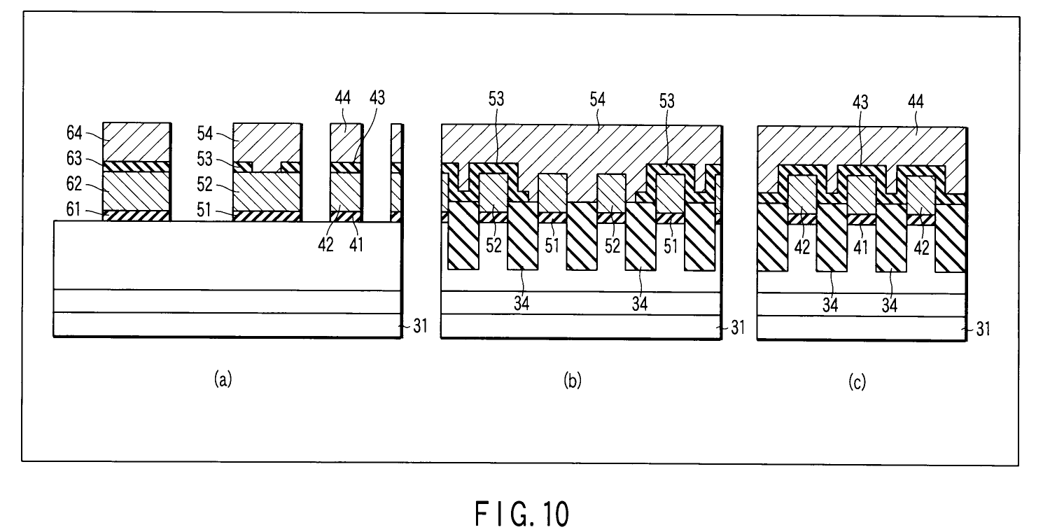

As shown in FIG. 10, a mask material (not shown) is formed on the electrically conductive film 44a by the CVD and the lithography process, for example. The mask material has a pattern which remains above the regions where the gate structures of the cell transistor 11 and the select gate transistors 22 and 23 are to be formed. The electrically conductive film 44a, the insulating film 43a, the electrically conductive film 42a and the insulating film 41a are partially removed by the anisotropic etching such as RIE using this mask material. As a result, the tunnel insulating films 41, 51 and 61, the floating gate electrodes 42, 52 and 62, the inter-electrode insulating films 43, 53 and 63, and the control gate electrodes 44, 54 and 64 are formed.

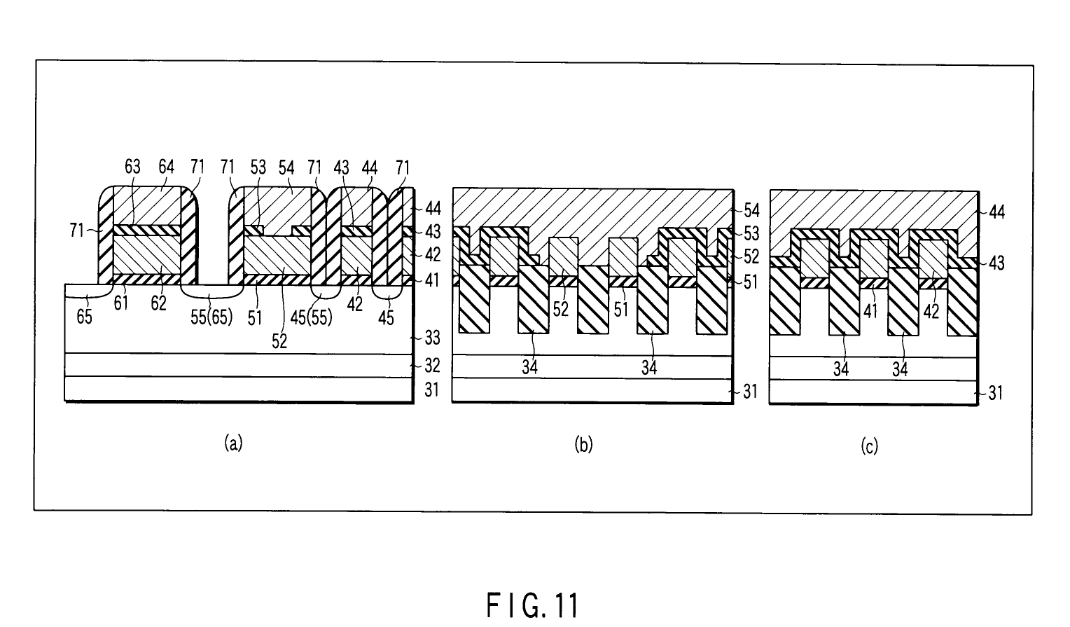

As shown in FIG. 11, the source/drain regions 45, 55 and 65 are formed by the ion injection using the control gate electrodes 44, 54 and 64 as a mask. An insulating film 71 is formed on side surfaces of the tunnel insulating films 41, 51 and 61, the floating gate electrodes 42, 52 and 62, the inter-electrode insulating films 43, 53 and 63, and the control gate electrodes 44, 54 and 64 by CVD and etching.

As shown in FIG. 3, insulating films 72 and 73 are sequentially formed on the entire surface of the structure obtained by the above steps by CVD, for example. A wiring groove for the bit line 15 and a hole for the plug 74 are formed by the lithography process and the anisotropic etching such as RIE. An electrically conductive material is embedded by the CVD method so that the bit line 15 and the plug 74 are formed.

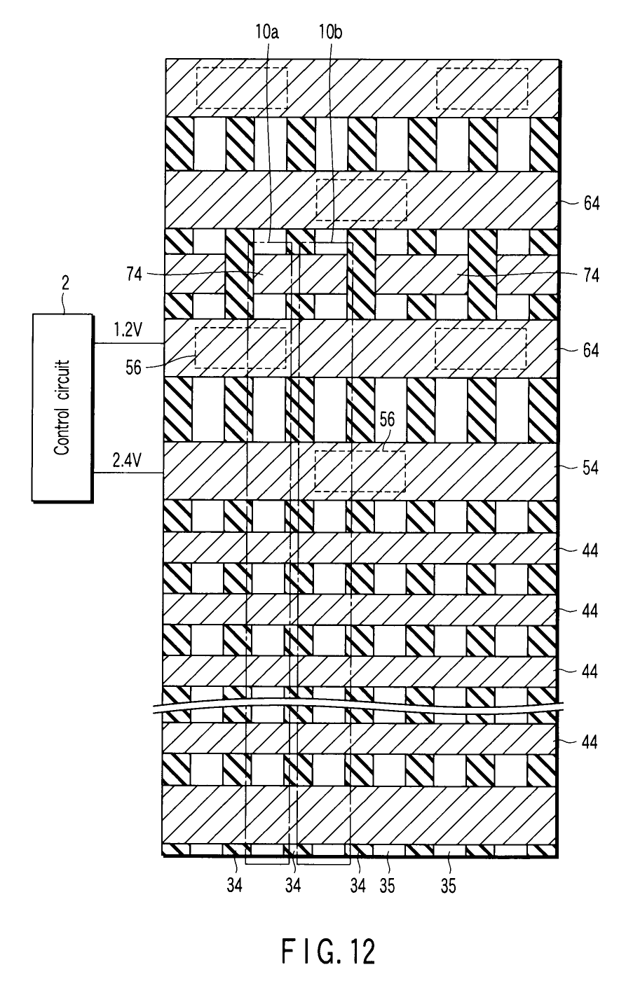

The operation of the semiconductor memory device according to one embodiment of the present invention will be described below with reference to FIGS. 12 to 17.

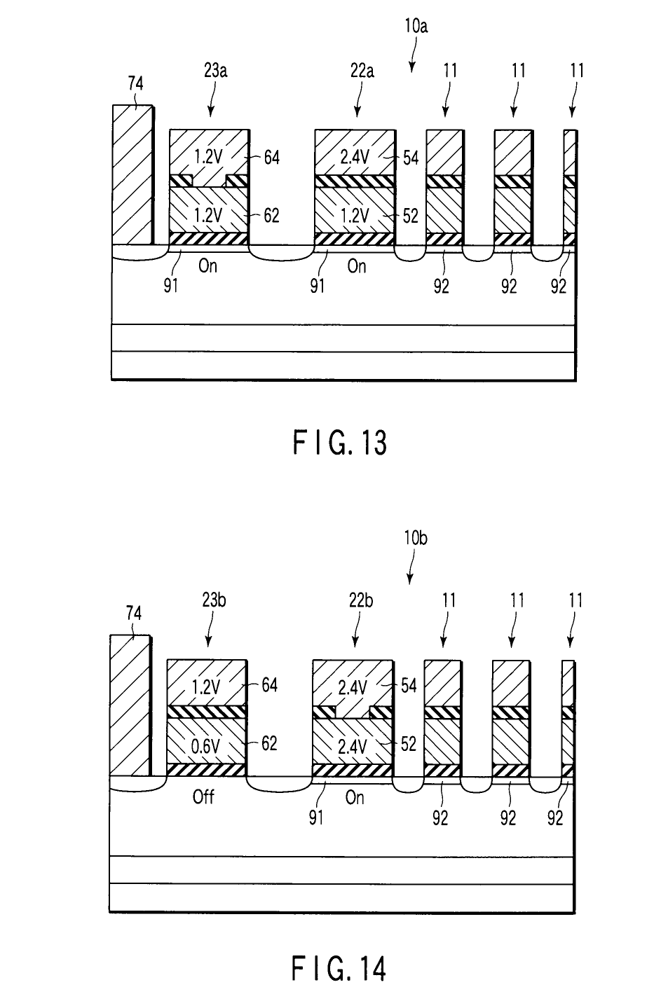

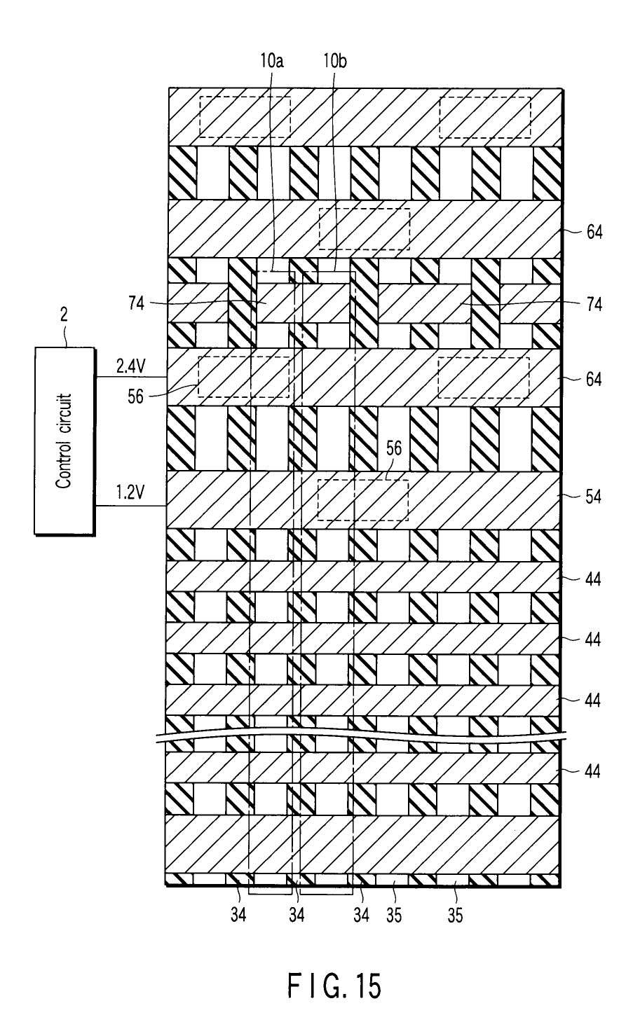

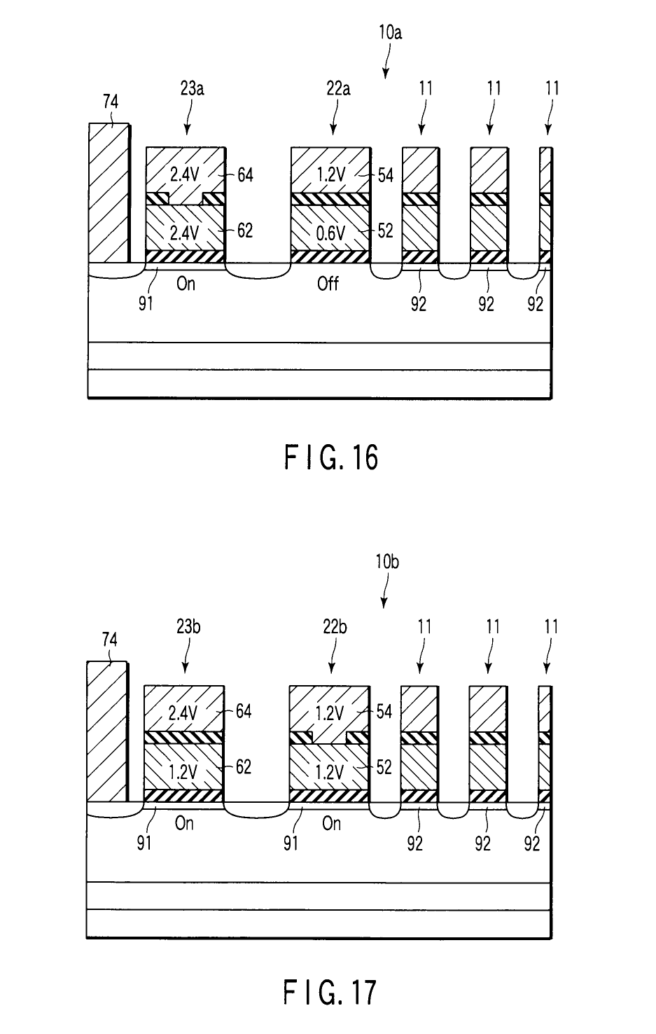

FIGS. 12 and 15 are plan views each illustrating one state of the operation of the semiconductor memory device according to one embodiment of the present invention, and correspond to the plan view of FIG. 2. FIGS. 13 and 14 are cross-sectional views corresponding to FIG. 3(a) illustrating the NAND strings 10a and 10b surrounded by one dotted and dashed line of FIG. 12. FIGS. 16 and 17 are cross-sectional views corresponding to FIG. 3(a) illustrating the NAND strings 10a and 10b surrounded by one dotted and dashed line of FIG. 15. The NAND strings 10a and 10b share the bit line 15.

As shown in FIGS. 13 and 16, the control gate electrode 54 and the floating gate electrode 52 of the select gate transistor 22 (22a) in the NAND string 10a are separated from each other, and the control gate electrode 64 and the floating gate electrode 62 of the select gate transistor 23 (23a) are connected to each other. On the other hand, as shown in FIGS. 14 and 17, the control gate electrode 54 and the floating gate electrode 52 of the select gate transistor 22 (22b) in the NAND string 10b are connected to each other, and the control gate electrode 64 and the floating gate electrode 62 of the select gate transistor 23 (23b) are separated from each other.

FIGS. 12 to 14 illustrate a state wherein the NAND string 10a is selected and the NAND string 10b is not selected. On the other hand, FIGS. 16 and 17 illustrate a state wherein the NAND string 10a is not selected and the NAND string 10b is selected. FIGS. 13, 14, 16 and 17 illustrate only elements necessary for the description, and the other elements are omitted. Reference symbols 91 and 92 denote channels.

The case wherein the NAND string 10a is selected will be described. As shown in FIGS. 12 to 14, a first potential is applied to the control gate electrode 54 by the control circuit 2. The first potential is sufficient for turning on the select gate transistors 22a, 22b, 23a and 23b regardless of connection or non-connection between the control gate electrodes 54 and 64 and the floating gate electrodes 52 and 62.

On the other hand, a second potential which is at least smaller than the first potential is applied to the control gate electrode 64 by the control circuit 2. The second potential is not less than a level sufficient for turning on the select gate transistors 22a, 22b, 23a and 23b connected to the control gate electrodes 54 and 64 and the floating gate electrodes 52 and 62 and is less than a level sufficient for turning on the select gate transistors 22a, 22b, 23a and 23b which are not connected to the control gate electrodes 54 and 64 and the floating gate electrodes 52 and 62.

The first potential and the second potential are determined by various factors such as dimensions of the layers of the select gate transistors 22a, 22b, 23a and 23b, and impurity density of the channel regions. When the potential is applied to the select gate transistors 22a, 22b, 23a and 23b which are not connected to the control gate electrodes 54 and 64 and the floating gate electrodes 52 and 62, a potential which is half of the applied potential to the control gate electrodes 54 and 64 is generated on the floating gate electrodes 52 and 62 by coupling. By using this phenomenon, the first potential is set so that the select gate transistors 22a, 22b, 23a and 23b can be turned on even by a half of the potential, and the second potential is set so that the select gate transistors 22a, 22b, 23a and 23b cannot be turned on by a half of the potential. For example, in the case wherein when the potential of 1V is generated on the floating gate electrodes 52 and 62, channels are formed on the select gate transistors 22a, 22b, 23a and 23b, the first potential and the second potential may be set to 2.4V and 1.2V, respectively.

In case of the above potentials are applied, as shown in FIG. 13, both the select gate transistors 22a and 23a are turned on in the NAND string 10a. As a result, the cell transistor 11 is electrically connected to the bit line 15. The potential to be applied to the cell transistor 11 at the time of writing is the same as the case wherein the embodiment of the present invention is not used.

On the other hand, as shown in FIG. 14, the select gate transistor 22b is turned on in the NAND string 10b, but the select gate transistor 23b is not turned on. For this reason, the cell transistor 11 and the bit line 15 are electrically separated from each other.

The case wherein the NAND string 10b is selected is described below. As shown in FIGS. 15 to 17, the second potential is applied to the control gate electrode 54, and the first potential is applied to the control gate electrode 64. As a result, as shown in FIG. 16, the select gate transistor 23b is turned on, but the select gate transistor 22b is not turned on. For this reason, in the NAND string 10a, the cell transistor 11 is electrically separated from the bit line 15. On the other hand, as shown in FIG. 17, both the select gate transistors 22b and 23b are turned on. As a result, in the NAND string 10b, the cell transistor 11 is electrically connected to the bit line 15.

The on/off state of the select gate transistors 22 and 23 is controlled according to the combination of the first and second potentials and presence/absence of the removal portion 56. In order that this control is securely made, at least properties including the threshold voltages of the select gate transistors 22 and 23 should be controlled strictly. On the other hand, as the miniaturization of the semiconductor memory device is improved, it is more difficult to uniform the properties. Particularly, an operation margin is small in the case wherein the second potential (lower potential) is applied to the control gate electrodes 54 and 64 so that the select gate transistors 22 and 23 having the removal portion 56 are turned on. For this reason, a margin for the manufacturing variation for ensuring this operation is small.

Therefore, a method for varying the impurity density in the channel regions for the threshold control so as to vary the thresholds of the select gate transistors 22 and 23 may be used. In the above description, the threshold voltages of the select gate transistors 22 and 23 are the same (for example, 1V). On the contrary, for example, only the thresholds of the select gate transistors 22 and 23 having the removal portion 56 are made to be lower. As a result, the select gate transistors 22 and 23 having the removal portion 56 are easily turned on by the second potential. As a result, the margin for the manufacturing variation of the select gate transistors 22 and 23 can be alleviated.

Such a structure may be realized by forming the removal portion 56 at the steps in FIGS. 8(a), 8(b) and 8(c) and injecting impurities into the channel region through the opening of the mask material 82 via the electrically conductive film 42a. The impurities reduce the thresholds of the select gate transistors 22 and 23 including the channel regions into which the impurities are injected.

In the semiconductor memory device according to the embodiment of the present invention, the two NAND strings 10 are connected to one bit line 15. When the number of the bit line contacts 74 is reduced, the miniaturization of the semiconductor memory device is enabled.

One terminal of the series structure of the memory cell transistor in one NAND string is connected to the bit line 15 via the two stacked-gate-structure select gate transistors 22 and 23 which are connected in series. In one of the select gate transistors 22 and 23 in one NAND string 10, one of the two select gate transistors 22 in the two NAND strings 10 sharing one bit line 15, and the select gate transistors 22 and 23 which satisfy one of the two select gate transistors 23, the floating gate electrodes 52 and 62 are connected to the control gate electrodes 54 and 64, respectively. When a suitable potential is applied to the control gate electrodes 54 and 64, only one of the two NAND strings 10 sharing the bit line 15 is connected to the bit line 15. This structure may be realized by using the manufacturing steps for the conventional NAND flash memory without using an expensive semiconductor manufacturing device. For this reason, the two NAND strings 10 share one bit line so that the semiconductor device can be miniaturized without increasing the manufacturing cost.

According to the present invention, the semiconductor memory device which can be miniaturized and manufactured at low cost can be provided by the following constitutions.

[First Constitution]
A first cell transistor series including memory cell transistors connected in series;
A first selecting transistor whose one terminal is connected to one terminal of the first cell transistor series;
A second selecting transistor connected between the other terminal of the first selecting transistor and a bit line; and
A third selecting transistor connected between the other terminal of the first cell transistor series and a source line.

The first and second selecting transistors have a first conductive film, an inter-electrode insulating film and a second conductive film which are stacked on a semiconductor substrate. In one of the first and second selecting transistors, the first and second conductive films are connected to each other, and in the other transistor, the first and second conductive films are separated from each other.

The first and second conductive films of the first selecting transistor are connected to each other, and the first and second conductive films of the second selecting transistor are separated from each other. Instead of this structure, the first and second conductive films of the first selecting transistor may be separated from each other, and the first and second conductive films of the second selecting transistor may be connected to each other.

The threshold voltages of the first and second selecting transistors may be the same or different.

At the time of reading/writing, the potential to be applied to the second conductive film of the first selecting transistor is different from the potential to be applied to the second conductive film of the second selecting transistor.

[Second Constitution]
A first cell transistor series and a second cell transistor series arranged adjacently in a row direction, each of them having memory cell transistors connected in series;
A first selecting transistor whose one terminal is connected to one terminal of the first cell transistor series;
A second selecting transistor connected between the other terminal of the first selecting transistor and a first bit line;
A third selecting transistor connected between the other terminal of the first cell transistor series and a source line;
A fourth selecting transistor whose one terminal is connected to one terminal of the second cell transistor series;
A fifth selecting transistor connected between the other terminal of the fourth selecting transistor and a second bit line; and
A sixth selecting transistor connected between the other terminal of the second cell transistor series and the source line.

The first, second, fourth and fifth selecting transistors have a first conductive film, an inter-electrode insulating film and a second conductive film which are stacked on a semiconductor substrate. In the first and fifth selecting transistors, the first and second conductive films are connected to each other, and in the second and fourth selecting transistors, the first and second conductive films are separated from each other.

The second conductive films of the first and fourth selecting transistors are connected to each other, and the second conductive films of the second and fifth selecting transistors are connected to each other.

The threshold voltages of the first, second, fourth and fifth selecting transistors are the same, and the first potential to be applied to the second conductive films of the first and fourth selecting transistors is different from the second potential to be applied to the second conductive films of the second and fifth selecting transistors.

When the first potential is higher than the second potential, the first, fourth and fifth selecting transistors are turned on, and the second selecting transistor is turned off. When the first potential is higher than the second potential, reading/writing is executed on one selecting cell in the second cell transistor series.

When the second potential is higher than the first potential, the first, second and fifth selecting transistors are turned on, and the fourth selecting transistor is turned off. When the second potential is higher than the first potential, reading/writing is executed on one selecting cell in the first cell transistor series.

As to the threshold voltages of the first, second, fourth and fifth selecting transistors, the threshold voltages of the first and fourth selecting transistors are the same, and the threshold voltages of the second and fifth selecting transistors are the same. The threshold voltages of the first and second selecting transistors may be different, and the threshold voltage of the fourth and fifth selecting transistors may be different.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
a first cell transistor series including memory cell transistor connected in series;
a first selecting transistor whose one terminal is connected to one terminal of the first cell transistor series;
a second selecting transistor connected between the other terminal of the first selecting transistor and a bit line; and
a third selecting transistor connected between the other terminal of the first cell transistor series and a source line,
wherein the first and second selecting transistors have a first conductive film, an inter-electrode insulating film and a second conductive film which are stacked on a semiconductor substrate, and
in one of the first and second selecting transistors, the first and second conductive films are connected to each other, and in the other transistor, the first and second conductive films are separated from each other.

2. The semiconductor memory device according to claim 1, wherein the first and second conductive films of the first selecting transistor are connected to each other, and the first and second conductive films of the second selecting transistor are separated from each other.

3. The semiconductor memory device according to claim 1, wherein the first and second conductive films of the first selecting transistor are separated from each other, and the first and second conductive films of the second selecting transistor are connected to each other.

4. The semiconductor memory device according to claim 1, wherein threshold voltages of the first and second selecting transistors are equal to each other.

5. The semiconductor memory device according to claim 1, wherein threshold voltages of the first and second selecting transistors are different from each other.

6. The semiconductor memory device according to claim 1, wherein an electric potential to be applied to the second conductive film of the first selecting transistor is different from an electric potential to be applied to the second conductive film of the second selecting transistor.

7. The semiconductor memory device according to claim 1, wherein the first and second selecting transistors are connected in series via a source/drain diffusion layer in the semiconductor substrate.

8. The semiconductor memory device according to claim 1, wherein the first cell transistor series constitutes a NAND string.

9. A semiconductor memory device comprising:
a first cell transistor series and a second cell transistor series arranged adjacently in a row direction, each having memory cell transistors connected in series;
a first selecting transistor whose one terminal is connected to one terminal of the first cell transistor series;
a second selecting transistor connected between the other terminal of the first selecting transistor and a first bit line;
a third selecting transistor connected between the other terminal of the first cell transistor series and a source line;
a fourth selecting transistor whose one terminal is connected to one terminal of the second cell transistor series;
a fifth selecting transistor connected between the other terminal of the fourth selecting transistor and a second bit line; and
a sixth selecting transistor connected between the other terminal of the second cell transistor series and the source line,
wherein the first, second, fourth and fifth selecting transistors have a first conductive film, an inter-electrode insulating film and a second conductive film which are stacked on a semiconductor substrate, and
in the first and fifth selecting transistors, the first and second conductive films are connected to each other, and in the second and fourth selecting transistors, the first and second conductive films are separated from each other.

10. The semiconductor memory device according to claim 9, wherein the second conductive films of the first and fourth selecting transistors are connected to each other, and the second conductive films of the second and fifth selecting transistors are connected to each other.

11. The semiconductor memory device according to claim 10, wherein threshold voltages of the first, second, fourth and fifth selecting transistors are equal to one another.

12. The semiconductor memory device according to claim 11, wherein a first electric potential to be applied to the second conductive films of the first and fourth selecting transistors is different from a second electric potential to be applied to the second conductive films of the second and fifth selecting transistors.

13. The semiconductor memory device according to claim 12, wherein when the first electric potential is higher than the second electric potential, the first, fourth and fifth selecting transistors are turned on, and the second selecting transistor is turned off.

14. The semiconductor memory device according to claim 13, wherein when the first electric potential is higher than the second electric potential, reading/writing is executed on one selecting cell in the second cell transistor series.

15. The semiconductor memory device according to claim 12, wherein when the second electric potential is higher than the first electric potential, the first, second and fifth selecting transistors are turned on, and the fourth selecting transistor is turned off.

16. The semiconductor memory device according to claim 15, wherein when the second electric potential is higher than the first electric potential, reading/writing is executed on one selecting cell in the first cell transistor series.

17. The semiconductor memory device according to claim 10, wherein threshold voltages of the first and fourth selecting transistors are equal to each other, threshold voltages of the second and fifth selecting transistors are equal to each other, threshold voltages of the first and second selecting transistors are different from each other, and threshold voltages of the fourth and fifth selecting transistors are different from each other.

18. The semiconductor memory device according to claim 17, wherein a first electric potential to be applied to the second conductive films of the first and fourth selecting transistors is different from a second electric potential to be applied to the second conductive films of the second and fifth selecting transistors.

19. The semiconductor memory device according to claim 9, wherein the first and second selecting transistors are connected in series via a first source/drain diffusion layer in the semiconductor substrate, and the fourth and fifth selecting transistors are connected in series via a second source/drain diffusion layer in the semiconductor substrate.

20. The semiconductor memory device according to claim 9, wherein the first cell transistor series and the second cell transistor series constitute NAND strings, respectively.
